(19) United States
(12) Patent Application Publication
(10) Pub. No.: US 2026/0186087 A1
(43) Pub. Date: Jul. 2, 2026

(54) Wireless Clock Synchronization Device and Method for Magnetic Resonance Imaging, and Magnetic Resonance Imaging System

(71) Applicant: Siemens Healthineers AG, Forchheim (DE)

(72) Inventors: Qian Yun Pang, Shenzhen (CN); Qiu Yi Zhang, Shenzhen (CN); JianMin Wang, Shenzhen (CN)

(73) Assignee: Siemens Healthineers AG, Forchheim (DE)

(21) Appl. No.: 19/432,782

(22) Filed: Dec. 24, 2025

(30) Foreign Application Priority Data
Dec. 26, 2024 (CN) 202411977447.4

(51) Int. Cl. G01R 33/36

(52) U.S. Cl. CPC G01R 33/3628; G01R 33/3607; G01R 33/3621

(57) ABSTRACT

The disclosure is directed to a wireless clock synchronization device and method for magnetic resonance imaging. The device may include a main controller that determines a radio-frequency carrier frequency for a next cycle according to a current radio-frequency carrier frequency and a set radio-frequency carrier frequency adjustment step size, and sends the radio-frequency carrier frequency for the next cycle to a radio-frequency carrier signal generator. The radio-frequency carrier signal generator generates a radio-frequency carrier signal according to the radio-frequency carrier frequency for the next cycle and sends the radio-frequency carrier signal to a system clock signal modulator. The system clock signal modulator modulates a system clock signal onto the radio-frequency carrier signal and emits it through a first radio-frequency transmitter. The probability that a magnetic resonance wireless coil is in a blind spot position is greatly reduced, thereby increasing the spatial range of use of the wireless coil.

### CROSS REFERENCE TO RELATED APPLICATIONS

This patent application claims priority to Chinese Patent Application No. 202411977447.4, filed Dec. 26, 2024, which is incorporated herein by reference in its entirety.

### BACKGROUND

### Field

The present disclosure relates to the technical field of medical imaging, and in particular to a wireless clock synchronization device and method for Magnetic Resonance (MR) imaging, and to a magnetic resonance imaging system.

### Related Art

In a Magnetic Resonance (MR) imaging system, when an MR signal is transmitted in a wireless manner, a wireless coil receives the MR signal and sends the MR signal in a wireless manner to a system end. The system end reconstructs an image according to the MR signal, thereby obtaining the MR image. To ensure the normal operation of the entire link, clock synchronization is required between the wireless coil end and the system end.

### BRIEF DESCRIPTION OF THE DRAWINGS/FIGURES

The accompanying drawings, which are incorporated herein and form a part of the specification, illustrate the embodiments of the present disclosure and, together with the description, further serve to explain the principles of the embodiments and to enable a person skilled in the pertinent art to make and use the embodiments.

FIG. 1 is an architecture diagram for clock synchronization using radio-frequency wireless communication.

FIG. 2 is a schematic diagram of a wireless transmission blind spot area within an examination bore of MR examination equipment for signals of four different frequencies.

FIG. 3 is a schematic structural diagram of a wireless clock synchronization device for MR imaging provided in an embodiment of the present disclosure.

FIG. 4 is a schematic structural diagram of a radio-frequency carrier signal generator provided in an embodiment of the present disclosure.

FIG. 5 is a schematic structural diagram of a radio-frequency carrier signal generator provided in another embodiment of the present disclosure.

FIG. 6 is a schematic structural diagram of a radio-frequency carrier signal generator provided in yet another embodiment of the present disclosure.

FIG. 7 is a schematic structural diagram of a wireless clock synchronization device for MR imaging provided in another embodiment of the present disclosure.

FIG. 8 is a schematic structural diagram of a wireless clock synchronization device for MR imaging provided in yet another embodiment of the present disclosure.

FIG. 9 shows a curve of

$$10 l g \frac{p 2}{p 1}$$

as a function of a frequency of a signal emitted by a radio-frequency antenna 1 when a radio-frequency antenna 2 moves to a certain position in an examination bore of MR examination equipment, with both radio-frequency antennas 1 and 2 being in the 2.4 GHz band, in an application example of the present disclosure.

FIG. 10 shows a curve of

$$10 l g \frac{p 2}{p 1}$$

as a function of a frequency of a signal emitted by a radio-frequency antenna 1 when a radio-frequency antenna 2 moves to a certain position in an examination bore of MR examination equipment, with both radio-frequency antennas 1 and 2 being in the 5.8 GHz band, in an application example of the present disclosure.

FIG. 11 is a flowchart of a wireless clock synchronization method for MR imaging provided in an embodiment of the present disclosure.

The exemplary embodiments of the present disclosure will be described with reference to the accompanying drawings. Elements, features and components that are identical, functionally identical and have the same effect are—insofar as is not stated otherwise—respectively provided with the same reference character.

### DETAILED DESCRIPTION

In the following description, numerous specific details are set forth in order to provide a thorough understanding of the embodiments of the present disclosure. However, it will be apparent to those skilled in the art that the embodiments, including structures, systems, and methods, may be practiced without these specific details. The description and representation herein are the common means used by those experienced or skilled in the art to most effectively convey the substance of their work to others skilled in the art. In other instances, well-known methods, procedures, components, and circuitry have not been described in detail to avoid unnecessarily obscuring embodiments of the disclosure. The connections shown in the figures between functional units or other elements can also be implemented as indirect connections, where a connection can be wireless or wired. Functional units can be implemented as hardware, software or a combination of hardware and software.

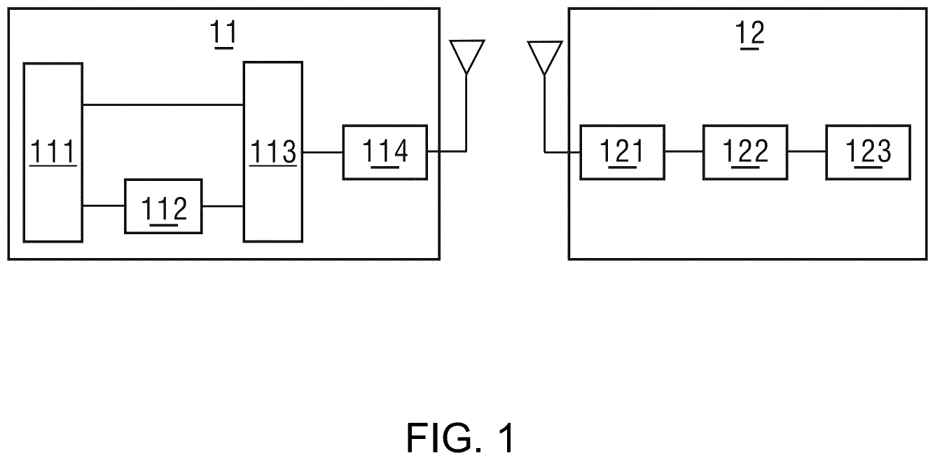

A clock synchronization scheme may use radio-frequency wireless communication to perform clock synchronization. FIG. 1 is an example system for performing clock synchronization by using the radio-frequency wireless communication. As shown in FIG. 1, 11 is a system end, 12 is a wireless coil end, 111 is a system clock, 112 is a radio-frequency carrier signal generator, 113 is an amplitude modulator, 114 is a radio-frequency transmitter, 121 is a radio-frequency receiver, 122 is an envelope detection module, and 123 is a clock phase-locked loop. The clock synchronization process in FIG. 1 may include the following:

At the system end 11, the radio-frequency carrier signal generator 112 generates a single-tone radio-frequency carrier signal (that is, the frequency of the radio-frequency carrier signal is always the same frequency) with a clock signal (assuming a frequency of 10 MHz) output by the system clock 111 as a reference; then, the amplitude modulator 113 modulates a system clock signal onto the radio-frequency carrier signal through amplitude modulation, so that the envelope of the modulated radio-frequency signal changes with the system clock signal; and thereafter, the radio-frequency transmitter 114 sends out the modulated radio-frequency signal through an antenna.

At the wireless coil end 12, the radio-frequency receiver 121 receives the radio-frequency signal, and sends the radio-frequency signal to the envelope detection module 122; the envelope detection module 122 obtains a 10 MHz signal through envelope detection and sends this signal as a reference clock signal of the wireless coil end to the clock phase-locked loop 123; when the amplitude of the reference clock signal meets an input power requirement of the clock phase-locked loop 123, the clock phase-locked loop 123 synchronizes a crystal oscillation signal generated by itself with the reference clock signal, and uses the synchronized crystal oscillation signal as a reference clock signal of the wireless coil end 12.

As an example, the transmit and receive antenna of the aforementioned clock synchronization scheme may be a single-transmit, single-receive scheme. When the wireless coil is placed inside an examination bore of MR examination equipment, the metallic properties of the MR transmitting coil (i.e., the body coil placed inside the housing of the MR examination equipment) and the radio-frequency shielding layer cause radio-frequency signal reflection. Therefore, the wireless clock link is actually a multipath transmission. Due to the multipath effect, radio-frequency signals will superimpose and become stronger at some positions in space, and will superimpose and become weaker at some positions. When the radio-frequency signal value is very small, approaching 0, a signal blind spot area will appear. This blind spot causes the clock receiving link at the wireless coil end to be unable to operate normally. Therefore, when using the wireless coil, its position needs to be adjusted to avoid areas where the clock receiving link cannot operate normally. This greatly limits the area range of use of the wireless coil and increases the difficulty for operators to use the wireless coil.

In an example technique for signal blind spots in the clock synchronization process of MR imaging systems may include the following:
I. A clock indicator light is connected to the clock phase-locked loop 123 of the wireless coil end 12. The operator adjusts the position of the wireless coil in the examination bore of the MR examination equipment. When the wireless coil is in a certain position, the indicator light is bright enough, then it indicates that the signal reception effect at this position is good enough. Therefore, it is determined that the wireless coil should be placed in this position during the MR examination process. The disadvantage of this method is that it requires manual intervention, and the position of the wireless coil is limited.
II. An Automatic Gain Control (AGC) circuit is added to the wireless coil end 12. The disadvantage of this method is that even with the addition of the AGC circuit, the dynamic range of the received power at the wireless coil end 12 is still limited, and it cannot completely solve the blind spot problem caused by the multipath effect.
III. Increasing the number of transmit links and receive links, i.e., more transmit and more receive, can increase the space available for placing the wireless coil. The disadvantage of this method is that a lot of circuits are added, thereby increasing the size and power consumption of the wireless coil, and it cannot completely solve the problem of limited usage positions of the wireless coil caused by the blind spots.

Aspects of the disclosure advantageously improve on the above example techniques and operations, and provide a wireless clock synchronization device and method for MR imaging that reduce the probability that the MR wireless coil is in a blind spot position during clock synchronization, and provide an MR imaging system to reduce the probability that the MR wireless coil is in a blind spot position during clock synchronization.

A wireless clock synchronization device for magnetic resonance imaging, the device may comprise: a system clock, a main controller, a radio-frequency carrier signal generator, a system clock signal modulator, and a first radio-frequency transmitter located at a magnetic resonance system end.

The system clock may generate a system clock signal and may output the system clock signal to the system clock signal modulator. When a radio-frequency carrier frequency adjustment timing determined according to a preset radio-frequency carrier frequency adjustment cycle arrives, the main controller determines a radio-frequency carrier frequency for a next cycle according to a current radio-frequency carrier frequency and a set radio-frequency carrier frequency adjustment step size, and sends the radio-frequency carrier frequency for the next cycle to the radio-frequency carrier signal generator. The radio-frequency carrier signal generator generates a radio-frequency carrier signal of a corresponding frequency according to the radio-frequency carrier frequency for the next cycle, and sends the radio-frequency carrier signal to the system clock signal modulator. The system clock signal modulator modulates a system clock signal onto the radio-frequency carrier signal and emits the modulated radio-frequency signal. The first radio-frequency transmitter emits the radio-frequency signal emitted from the system clock signal modulator.

A frequency adjustment cycle of the radio-frequency carrier signal in the main controller is less than an unlocking time margin of a clock phase-locked loop at a magnetic resonance wireless coil end.

In one or more aspects: (1) a value of the radio-frequency carrier frequency adjustment step size in the main controller is set according to a width of a frequency range corresponding to a identical blind spot position, (2) the value of the radio-frequency carrier frequency adjustment step size in the main controller is set according to the width of the frequency range corresponding to the identical blind spot position and a frequency range actually used by the first radio-frequency transmitter, (3) the radio-frequency carrier frequency adjustment step size in the main controller is greater than the width of the frequency range corresponding to the identical blind spot position, or (4) the radio-frequency carrier frequency adjustment step size in the main controller is not less than half the width of the frequency range corresponding to the identical blind spot position, and not greater than the width of the frequency range corresponding to the identical blind spot position.

The radio-frequency carrier signal generator may comprise: a frequency-to-voltage conversion module (frequency-to-voltage converter) and a voltage controlled crystal oscillator. The frequency-to-voltage conversion module may convert the radio-frequency carrier frequency for the next cycle into an input control voltage of the voltage controlled crystal oscillator according to the radio-frequency carrier frequency for the next cycle and a correspondence between output frequencies of the voltage controlled crystal oscillator and input control voltages, and may send the input control voltage to the voltage controlled crystal oscillator. The voltage controlled crystal oscillator may receive the input control voltage sent from the frequency-to-voltage conversion module, generates a crystal oscillation signal with a frequency corresponding to the input control voltage, and uses the crystal oscillation signal as a radio-frequency carrier signal.

The radio-frequency carrier signal generator may comprise: a digital signal generator, a digital-to-analog converter, and a radio-frequency modulator. The digital signal generator determines a corresponding baseband frequency according to the radio-frequency carrier frequency for the next cycle sent from the main controller, generates a digital baseband signal according to the baseband frequency, and sends the digital baseband signal to the digital-to-analog converter. The digital-to-analog converter receives the digital baseband signal sent from the digital signal generator, converts the digital baseband signal into an analog baseband signal, and sends the analog baseband signal to the radio-frequency modulator. The radio-frequency modulator modulates the analog baseband signal onto a local oscillator signal to obtain a radio-frequency carrier signal with a frequency being the radio-frequency carrier frequency for the next cycle, and sends the radio-frequency carrier signal to the system clock signal modulator.

The radio-frequency carrier signal generator may comprise: a frequency controller, a direct digital synthesizer, and a radio-frequency modulator. The frequency controller determines a corresponding baseband frequency according to the radio-frequency carrier frequency for the next cycle sent from the main controller, and sends a frequency control command corresponding to the baseband frequency to the direct digital synthesizer. The direct digital synthesizer parses a baseband frequency from the frequency control command, generates an analog baseband signal according to the baseband frequency, and sends the analog baseband signal to the radio-frequency modulator. The radio-frequency modulator modulates the analog baseband signal onto a local oscillator signal to obtain a radio-frequency carrier signal with a frequency being the radio-frequency carrier frequency for the next cycle, and sends the radio-frequency carrier signal to the system clock signal modulator.

The device may further comprise: a first radio-frequency receiver, a demodulator, and a clock phase-locked loop located at a magnetic resonance wireless coil end. The first radio-frequency receiver receives a radio-frequency signal from the first radio-frequency transmitter and sends the radio-frequency signal to the demodulator. The demodulator demodulates the radio-frequency signal to obtain a signal with a frequency equal to the system clock frequency, and sends the signal as a reference clock signal to the clock phase-locked loop; when an amplitude of the reference clock signal sent from the demodulator meets an input power requirement of the clock phase-locked loop, the clock phase-locked loop synchronizes a crystal oscillation signal generated by itself with the reference clock signal, and uses the synchronized crystal oscillation signal as a reference clock signal at the magnetic resonance wireless coil end.

The device may further comprise: a blind spot measuring instrument, a test radio-frequency transmitter, and a test radio-frequency receiver. The blind spot measuring instrument may have two ports, a first port connected to the test radio-frequency transmitter and a second port connected to the test radio-frequency receiver, frequency bands of the test radio-frequency transmitter and the test radio-frequency receiver are the same as a frequency band of the first radio-frequency transmitter, both the test radio-frequency transmitter and the test radio-frequency receiver are located inside an examination bore of magnetic resonance examination equipment, the test radio-frequency transmitter is fixed in position, and the test radio-frequency receiver moves continuously in a measurement process. The blind spot measuring instrument generates a frequency sweep signal at a certain rate within a supported frequency range and sends the frequency sweep signal to the test radio-frequency transmitter through the first port while the test radio-frequency receiver sends a received radio-frequency signal to the blind spot measuring instrument through the second port, the blind spot measuring instrument calculates an amplitude ratio between a signal received at the second port and a signal sent from the first port in real time and sends the amplitude ratio to the main controller. The main controller may be further configured to: (1) when the amplitude ratio sent from the blind spot measuring instrument is found to be less than a preset blind spot threshold, determine that the test radio-frequency receiver is currently in a blind spot of a signal emitted by the test radio-frequency transmitter, and record a correspondence between the frequency of the signal currently emitted by the test radio-frequency transmitter and the blind spot position, (2) when the measurement ends, determine a width of a frequency range corresponding to an identical blind spot position according to all recorded correspondences between frequencies and blind spot positions, and (3) according to the width of the frequency range corresponding to the identical blind spot position, or according to the width of the frequency range corresponding to the identical blind spot position and a frequency range actually used by the first radio-frequency transmitter, set the radio-frequency carrier frequency adjustment step size.

A wireless clock synchronization method in magnetic resonance imaging, the method may comprise: when a radio-frequency carrier frequency adjustment timing determined according to a preset radio-frequency carrier frequency adjustment cycle arrives, by a main controller, determining a radio-frequency carrier frequency for a next cycle according to a current radio-frequency carrier frequency and a set radio-frequency carrier frequency adjustment step size, and sending the radio-frequency carrier frequency for the next cycle to a radio-frequency carrier signal generator; by the radio-frequency carrier signal generator, generating a radio-frequency carrier signal of a corresponding frequency according to the radio-frequency carrier frequency for the next cycle, and sending the radio-frequency carrier signal to a system clock signal modulator; by the system clock signal modulator, modulating a system clock signal onto the radio-frequency carrier signal and transmitting the modulated radio-frequency signal through a first radio-frequency transmitter.

A frequency adjustment cycle of the radio-frequency carrier signal is less than an unlocking time margin of a clock phase-locked loop at a magnetic resonance wireless coil end.

A value of the radio-frequency carrier frequency adjustment step size is set according to a width of a frequency range corresponding to an identical blind spot position; or the value of the radio-frequency carrier frequency adjustment step size is set according to the width of the frequency range corresponding to the identical blind spot position and a frequency range actually used by the first radio-frequency transmitter; or the radio-frequency carrier frequency adjustment step size is greater than the width of the frequency range corresponding to the identical blind spot position; or the radio-frequency carrier frequency adjustment step size is not less than half the width of the frequency range corresponding to the identical blind spot position, and not greater than the width of the frequency range corresponding to the identical blind spot position.

The radio-frequency carrier signal generator generating the radio-frequency carrier signal of the corresponding frequency according to the radio-frequency carrier frequency for the next cycle may comprise: by a frequency-to-voltage conversion module in the radio-frequency carrier signal generator, converting the radio-frequency carrier frequency for the next cycle into an input control voltage of a voltage controlled crystal oscillator in the radio-frequency carrier signal generator according to the radio-frequency carrier frequency for the next cycle and a correspondence between output frequencies of the voltage controlled crystal oscillator and input control voltages, and sending the input control voltage to the voltage controlled crystal oscillator; and by the voltage controlled crystal oscillator, generating a crystal oscillation signal with a frequency corresponding to the received input control voltage according to the input control voltage, and using the crystal oscillation signal as a radio-frequency carrier signal.

The radio-frequency carrier signal generator generating the radio-frequency carrier signal of the corresponding frequency according to the radio-frequency carrier frequency for the next cycle may comprise: by a digital signal generator in the radio-frequency carrier signal generator, determining a corresponding baseband frequency according to the radio-frequency carrier frequency for the next cycle sent from the main controller, generating a digital baseband signal according to the baseband frequency, and sending the digital baseband signal to a digital-to-analog converter in the radio-frequency carrier signal generator; by the digital-to-analog converter, converting the digital baseband signal into an analog baseband signal, and sending the analog baseband signal to a radio-frequency modulator in the radio-frequency carrier signal generator; and by the radio-frequency modulator, modulating the analog baseband signal onto a local oscillator signal to obtain a radio-frequency carrier signal with a frequency being the radio-frequency carrier frequency for the next cycle.

The radio-frequency carrier signal generator generating the radio-frequency carrier signal of the corresponding frequency according to the radio-frequency carrier frequency for the next cycle may comprise: by a frequency controller in the radio-frequency carrier signal generator, determining a corresponding baseband frequency according to the radio-frequency carrier frequency for the next cycle sent from the main controller, and sending a frequency control command corresponding to the baseband frequency to a direct digital synthesizer in the radio-frequency carrier signal generator; by the direct digital synthesizer, parsing a baseband frequency from the frequency control command, generating an analog baseband signal according to the baseband frequency, and sending the analog baseband signal to a radio-frequency modulator in the radio-frequency carrier signal generator; and by the radio-frequency modulator, modulating the analog baseband signal onto a local oscillator signal to obtain a radio-frequency carrier signal with a frequency being the radio-frequency carrier frequency for the next cycle.

Before the main controller determines the arrival of the radio-frequency carrier frequency adjustment timing according to the preset radio-frequency carrier frequency adjustment cycle, the method further may comprise: by a blind spot measuring instrument, generating a frequency sweep signal at a certain rate within a supported frequency range and sending the frequency sweep signal to a test radio-frequency transmitter through a first port while a test radio-frequency receiver sends a received radio-frequency signal to the blind spot measuring instrument through a second port of the blind spot measuring instrument, and by the blind spot measuring instrument, calculating an amplitude ratio between a signal received at the second port and a signal sent from the first port in real time and sending the amplitude ratio to the main controller; when the main controller finds that the amplitude ratio sent from the blind spot measuring instrument is less than a preset blind spot threshold, determining that the test radio-frequency receiver is currently in a blind spot of a signal emitted by the test radio-frequency transmitter, and recording a correspondence between the frequency of the signal currently emitted by the test radio-frequency transmitter and the blind spot position; when the measurement ends, determining a width of a frequency range corresponding to an identical blind spot position according to all recorded correspondences between frequencies and blind spot positions; and according to the width of the frequency range corresponding to the identical blind spot position, or according to the width of the frequency range corresponding to the identical blind spot position and a frequency range actually used by the first radio-frequency transmitter, setting the radio-frequency carrier frequency adjustment step size.

A magnetic resonance imaging system, the system comprising any one of the wireless clock synchronization devices for magnetic resonance imaging as described above.

In the embodiments of the present disclosure, when the radio frequency adjustment timing determined according to the preset radio-frequency carrier frequency adjustment cycle arrives, the main controller determines the radio-frequency carrier frequency for the next cycle according to the current radio-frequency carrier frequency and the set radio-frequency carrier frequency adjustment step size, and sends the radio-frequency carrier frequency for the next cycle to the radio-frequency carrier signal generator, thereby making the radio-frequency carrier frequency change continuously, reducing the probability that the MR wireless coil is in a blind spot position during clock synchronization, and increasing the range of use of the MR wireless coil.

In order to make the objectives, technical solutions, and advantages of the present disclosure clearer, the following embodiments are provided to further describe the present disclosure.

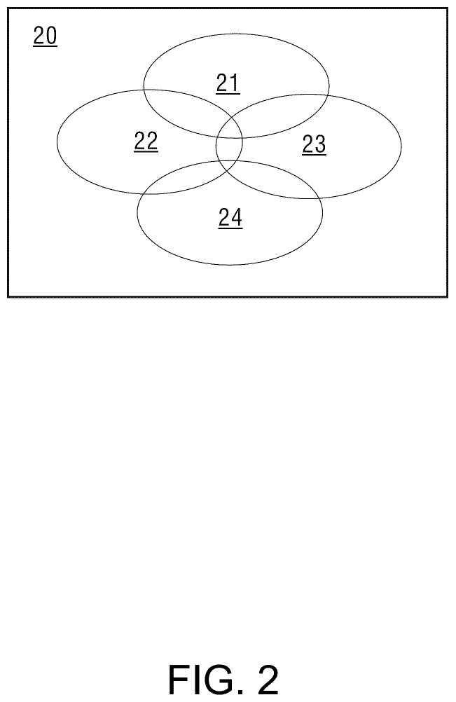

The inventors have found through experiments that in the same external environment, the wireless transmission blind spot areas of signals of different frequencies do not completely overlap. FIG. 2 shows a schematic diagram of wireless transmission blind spot areas of signals of four different frequencies in an examination bore of MR examination equipment. As shown in FIG. 2, 20 is a radio-frequency signal receiving area in the examination bore of the MR examination equipment, ellipse 21 is a wireless transmission blind spot area of a signal with frequency f1, ellipse 22 is a wireless transmission blind spot area of a signal with frequency f2, ellipse 23 is a wireless transmission blind spot area of a signal with frequency f3, and ellipse 24 is a wireless transmission blind spot area of a signal with frequency f4, where f1≠f2≠f3≠f4. As can be seen, the wireless transmission blind spot areas of any two frequencies do not completely overlap. Therefore, it can be concluded that when a sufficient number of single-tone signals of different frequencies are emitted, the time when a blind spot appears at a certain position will be greatly reduced. According to this finding, the following technical solution of the present disclosure is provided:

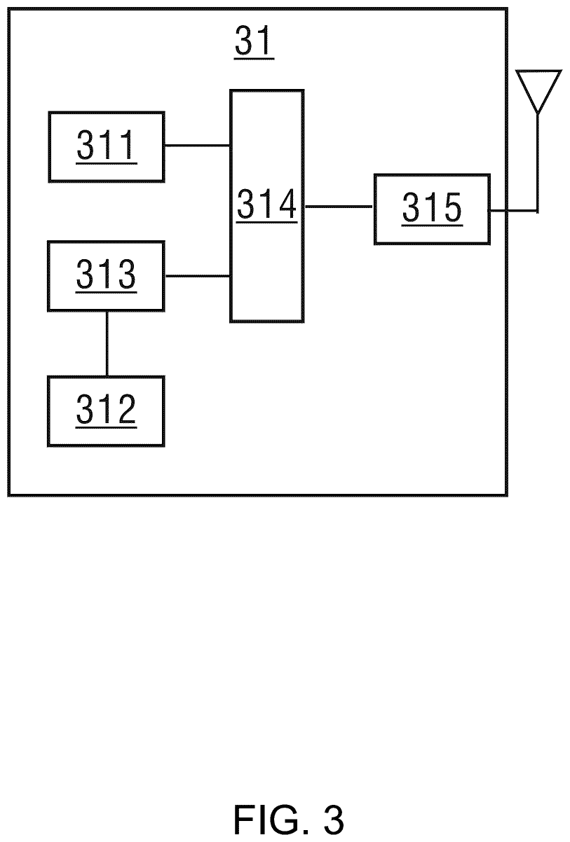

FIG. 3 is a schematic structural diagram of a wireless clock synchronization device for MR imaging provided in an embodiment of the present disclosure. As shown in FIG. 3, the device may include: a system clock 311 located at an MR system end 31, a main controller 312, a radio-frequency carrier signal generator 313, a system clock signal modulator 314, and a first radio-frequency transmitter 315. The system clock 311 generates a system clock signal and outputs the system clock signal to the system clock signal modulator 314. The wireless clock synchronization device may include processing circuitry configured to perform one or more functions and/or operations of the wireless clock synchronization device. Additionally, or alternatively, one or more components of the wireless clock synchronization device may include processing circuitry that is configured to perform one or more respective functions of the component(s).

When a radio-frequency carrier frequency adjustment timing determined according to a preset radio-frequency carrier frequency adjustment cycle arrives, the main controller 312 determines a radio-frequency carrier frequency for a next cycle according to a current radio-frequency carrier frequency and a set radio-frequency carrier frequency adjustment step size, and sends the radio-frequency carrier frequency for the next cycle to the radio-frequency carrier signal generator 313.

In practical applications, within a frequency range actually used by the first radio-frequency transmitter 315, the main controller 312 may start from the lowest frequency and use a radio-frequency carrier frequency adjustment step size to sequentially increase the radio-frequency carrier frequency in each frequency adjustment cycle. When the radio-frequency carrier frequency increases to the highest frequency in the frequency range actually used by the first radio-frequency transmitter 315, the main controller may then sequentially decrease from the highest frequency, or sequentially increase again from the lowest frequency. Alternatively, the main controller 312 may, within the frequency range actually used by the first radio-frequency transmitter 315, start from the highest frequency and use a radio-frequency carrier frequency adjustment step size to sequentially decrease the radio-frequency carrier frequency in each frequency adjustment cycle. When the radio-frequency carrier frequency decreases to the lowest frequency in the frequency range actually used by the first radio-frequency transmitter 315, the main controller may then sequentially increase from the lowest frequency, or sequentially decrease again from the highest frequency.

A frequency adjustment cycle of the radio-frequency carrier signal is less than an unlocking time margin of a clock phase-locked loop 323 at an MR wireless coil end. In practical applications, the frequency adjustment cycle of the radio-frequency carrier signal supported by the MR system end 31 is limited to a certain range. In addition, the unlocking time margin of the clock phase-locked loop 323 is also adjustable within a certain range. Therefore, by adjusting the unlocking time margin of the clock phase-locked loop 323, the frequency adjustment cycle of the radio-frequency carrier signal can be made less than the unlocking time margin of the clock phase-locked loop 323 at the MR wireless coil end.

The value of the radio-frequency carrier frequency adjustment step size is set according to the width of the frequency range corresponding to the identical blind spot position, or according to the width of the frequency range corresponding to the identical blind spot position and a frequency range actually used by a radio-frequency antenna (including the first radio-frequency transmitter 315 and a first radio-frequency receiver 321). For example, the radio-frequency carrier frequency adjustment step size may be set to be greater than the width of the frequency range corresponding to the identical blind spot position. However, in practical applications, considering that the frequency range actually used by the radio-frequency antenna may be small, if the radio-frequency carrier frequency adjustment step size is set too large, the frequency range actually used by the radio-frequency antenna will be used up within a small number of cycles. This does not effectively reduce the probability that the first radio-frequency receiver 321 is located in a blind spot. Therefore, the radio-frequency carrier frequency adjustment step size can be set by comprehensively considering the width of the frequency range corresponding to the identical blind spot position and the frequency range actually used by the radio-frequency antenna (including the first radio-frequency transmitter 315 and the first radio-frequency receiver 321). For example, when the frequency range actually used by the radio-frequency antenna is small, such as not greater than 0.1 GHz, the radio-frequency carrier frequency adjustment step size may be set to be not less than half the width of the frequency range corresponding to the identical blind spot position and not greater than the width of the frequency range corresponding to the identical blind spot position.

For example, for a 2.4 GHz radio-frequency antenna, if the frequency range actually used thereby is 2.3 GHz-2.5 GHz, and it has been found through experiments that for signals with frequencies of 2.3 GHz-2.5 GHz, the width of the frequency range corresponding to the blind spot of each signal in this range is substantially 20 MHz, then the value of the radio-frequency carrier frequency adjustment step size may be set to be greater than 20 MHz. For example, for a certain blind spot A, the frequency range corresponding to blind spot A is 2.376 GHz±10 MHz. That is, when the first radio-frequency transmitter 315 emits a signal with a frequency range of 2.376 GHz±10 MHz, if the first radio-frequency receiver 321 is located at point A, the ratio of the amplitude of the signal received by the first radio-frequency receiver 321 to the amplitude of the signal emitted by the first radio-frequency transmitter 315 is always less than a preset blind spot threshold. If the radio-frequency carrier frequency adjustment step size is set to be greater than 20 MHz, it can be ensured that when the first radio-frequency receiver 321 is set at point A, and when the frequency of the radio-frequency signal emitted by the first radio-frequency transmitter 315 in a certain cycle is exactly at 2.376 GHz±10 MHz, the first radio-frequency receiver 321 is exactly at a blind spot position. In the next cycle, the frequency of the radio-frequency signal emitted by the first radio-frequency transmitter 315 will not be at 2.376 GHz±10 MHz, so the first radio-frequency receiver 321 will not be at a blind spot position, thereby minimizing the probability that the first radio-frequency receiver 321 is at a blind spot position.

Alternatively, for a 2.4 GHz band radio-frequency antenna, if the frequency range actually used thereby is 2.4 GHz-2.483 GHz, considering that the 2.4 GHz-2.483 GHz band is relatively narrow, only 0.083 GHz, if the radio-frequency carrier frequency adjustment step size is set too large, the first radio-frequency transmitter 315 will quickly emit a round of signals within the 2.4 GHz-2.483 GHz range, which does not effectively reduce the probability that the first radio-frequency receiver 321 is at a blind spot position. Therefore, the radio-frequency carrier frequency adjustment step size can be set smaller, for example, to half the width of the frequency range corresponding to the identical blind spot position: 10 MHz.

The radio-frequency carrier signal generator 313 generates a radio-frequency carrier signal of a corresponding frequency according to the radio-frequency carrier frequency for the next cycle and sends the radio-frequency carrier signal to the system clock signal modulator 314.

The system clock signal modulator 314 modulates a system clock signal onto the radio-frequency carrier signal and emits the modulated radio-frequency signal.

In an optional embodiment, the system clock signal modulator 314 may modulate the system clock signal onto the radio-frequency carrier signal through amplitude modulation, so that the envelope of the modulated radio-frequency signal changes with the system clock signal.

The first radio-frequency transmitter 315 emits the radio-frequency signal emitted from the system clock signal modulator 314.

In the above embodiments, when the radio frequency adjustment timing determined according to the preset radio-frequency carrier frequency adjustment cycle arrives, the main controller determines the radio-frequency carrier frequency for the next cycle according to the current radio-frequency carrier frequency and the set radio-frequency carrier frequency adjustment step size, and sends the radio-frequency carrier frequency for the next cycle to the radio-frequency carrier signal generator, thereby making the radio-frequency carrier frequency change continuously, reducing the probability that the MR wireless coil is in a blind spot position during clock synchronization, increasing the range of use of the MR wireless coil, eliminating the need for both manual intervention and increase in the number of transmit and receive links, and reducing costs without increasing the volume and power consumption of the wireless coil end.

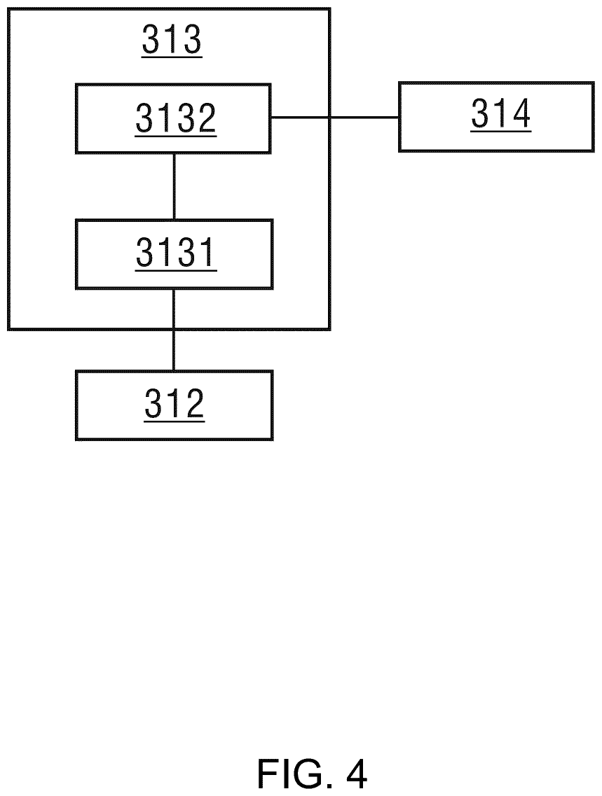

FIG. 4 is a schematic structural diagram of a radio-frequency carrier signal generator 313 provided in an embodiment of the present disclosure. As shown in FIG. 4, the radio-frequency carrier signal generator may include a frequency-to-voltage conversion module 3131 and a Voltage Controlled Crystal Oscillator (VCXO) 3132. The frequency-to-voltage conversion module 3131 converts the radio-frequency carrier frequency for the next cycle sent from the main controller 312 into an input control voltage of the VCXO according to the radio-frequency carrier frequency for the next cycle and a correspondence between output frequencies of the VCXO and input control voltages, and sends the input control voltage to the VCXO 3132. The radio-frequency carrier signal generator 313 may include processing circuitry configured to perform one or more functions and/or operations of the radio-frequency carrier signal generator 313. Additionally, or alternatively, one or more components of the radio-frequency carrier signal generator 313 may include processing circuitry that is configured to perform one or more respective functions of the component(s).

The VCXO 3132 is used to: receive the input control voltage sent from the frequency-to-voltage conversion module 3131, generate a crystal oscillation signal with a frequency corresponding to the input control voltage, use the crystal oscillation signal as a radio-frequency carrier signal, and send the radio-frequency carrier signal to the system clock signal modulator 314.

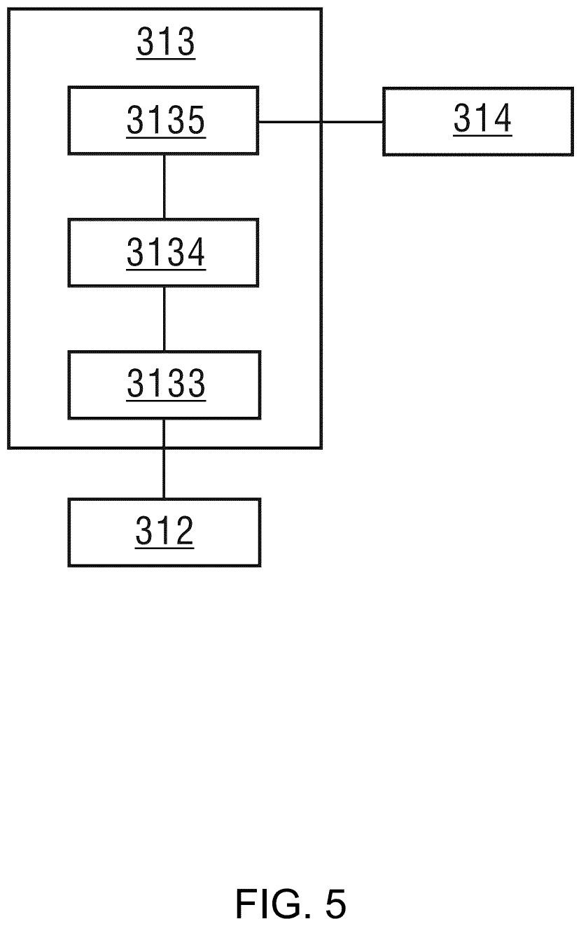

FIG. 5 is a schematic structural diagram of a radio-frequency carrier signal generator 313 provided in another embodiment of the present disclosure. As shown in FIG. 5, the radio-frequency carrier signal generator 313 may include a digital signal generator 3133, a Digital-to-Analog Converter (DAC) 3134, and a radio-frequency modulator 3135. The digital signal generator 3133 determines a corresponding baseband frequency according to the radio-frequency carrier frequency for the next cycle sent from the main controller 312, generates a digital baseband signal according to the baseband frequency, and sends the digital baseband signal to the DAC 3134. The radio-frequency carrier signal generator 313 may include processing circuitry configured to perform one or more functions and/or operations of the radio-frequency carrier signal generator 313. Additionally, or alternatively, one or more components of the radio-frequency carrier signal generator 313 may include processing circuitry that is configured to perform one or more respective functions of the component(s).

The digital signal generator 3133 determining the corresponding baseband frequency according to the radio-frequency carrier frequency for the next cycle sent from the main controller 312 may include the digital signal generator 3133 determining the baseband frequency corresponding to the radio-frequency carrier frequency for the next cycle according to its stored local oscillator frequency and its stored correspondence among baseband frequencies, local oscillator frequencies, and radio-frequency carrier frequencies. Then, the digital signal generator 3133 generates a baseband signal with a frequency being the baseband frequency.

The DAC 3134 receives the digital baseband signal sent from the digital signal generator 3133, converts the digital baseband signal into an analog baseband signal, and sends the analog baseband signal to the radio-frequency modulator 3135.

The radio-frequency modulator 3135 modulates the analog baseband signal sent from the DAC 3134 onto a local oscillator signal to obtain a radio-frequency carrier signal with a frequency being the radio-frequency carrier frequency for the next cycle, and sends the radio-frequency carrier signal to the system clock signal modulator 314.

The frequency of the local oscillator signal is the local oscillator frequency. By modulating the analog baseband signal sent from the DAC 3134 onto the local oscillator signal, a radio-frequency carrier signal with a frequency equal to the radio-frequency carrier frequency of the next cycle is obtained.

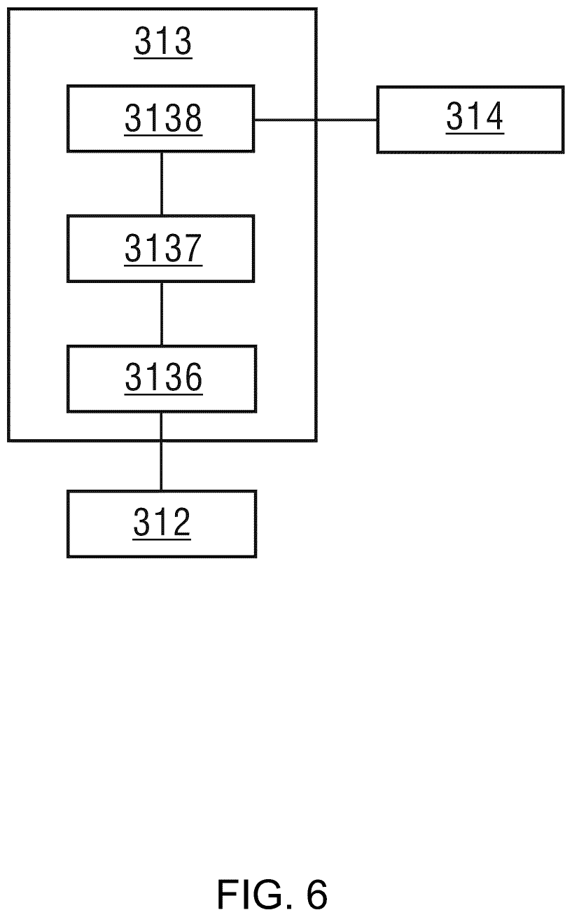

FIG. 6 is a schematic structural diagram of a radio-frequency carrier signal generator 313 provided in yet another embodiment of the present disclosure. As shown in FIG. 6, the radio-frequency carrier signal generator may include a frequency controller 3136, a Direct Digital Synthesizer (DDS) 3137, and a radio-frequency modulator 3138. The frequency controller 3136 determines a corresponding baseband frequency according to the radio-frequency carrier frequency for the next cycle sent from the main controller 312 and sends a frequency control command corresponding to the baseband frequency to the DDS 3137. The radio-frequency carrier signal generator 313 may include processing circuitry configured to perform one or more functions and/or operations of the radio-frequency carrier signal generator 313. Additionally, or alternatively, one or more components of the radio-frequency carrier signal generator 313 may include processing circuitry that is configured to perform one or more respective functions of the component(s).

The frequency controller 3136 determining the corresponding baseband frequency according to the radio-frequency carrier frequency for the next cycle sent from the main controller 312 may include the frequency controller 3136 determining the baseband frequency corresponding to the radio-frequency carrier frequency for the next cycle according to its stored local oscillator frequency and its stored correspondence among baseband frequencies, local oscillator frequencies, and radio-frequency carrier frequencies.

The DDS 3137 parses a baseband frequency from the frequency control command sent from the frequency controller 3136, generates an analog baseband signal according to the baseband frequency, and sends the analog baseband signal to the radio-frequency modulator 3138.

The radio-frequency modulator 3138 modulates the analog baseband signal sent from the DDS 3137 onto a local oscillator signal to obtain a radio-frequency carrier signal with a frequency being the radio-frequency carrier frequency for the next cycle, and sends the radio-frequency carrier signal to the system clock signal modulator 314.

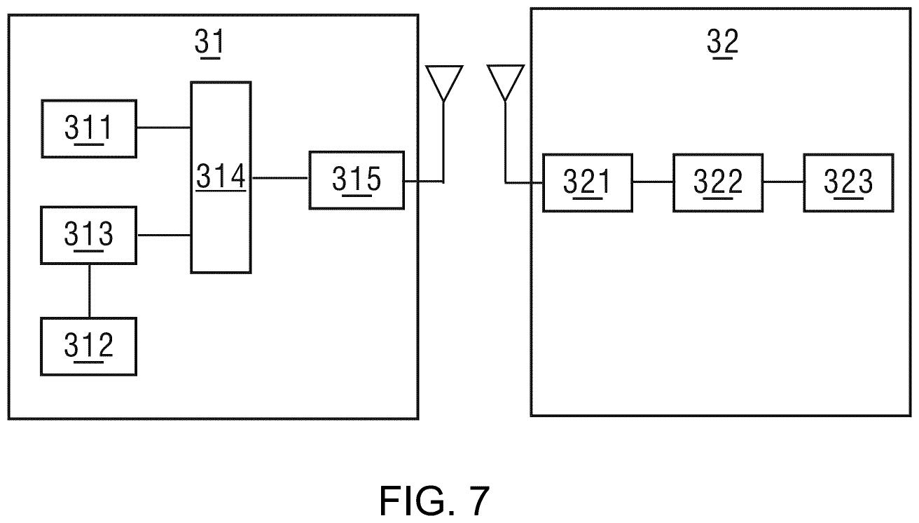

FIG. 7 is a schematic structural diagram of a wireless clock synchronization device for MR imaging provided in another embodiment of the present disclosure. As shown in FIG. 7, compared with the device shown in FIG. 3, the device shown in FIG. 7 has the following added: a first radio-frequency receiver 321, a demodulator 322, and a clock phase-locked loop 323 located at an MR wireless coil end 32. The first radio-frequency receiver 321 is used to receive a radio-frequency signal from the first radio-frequency transmitter 315 and send the radio-frequency signal to the demodulator 322. The wireless clock synchronization device may include processing circuitry configured to perform one or more functions and/or operations of the wireless clock synchronization device. Additionally, or alternatively, one or more components of wireless clock synchronization device may include processing circuitry that is configured to perform one or more respective functions of the component(s).

The demodulator 322 is used to demodulate the radio-frequency signal to obtain a signal with a frequency equal to the system clock frequency, and send the signal as a reference clock signal to the clock phase-locked loop 323.

When the system clock signal modulator 314 modulates the system clock signal onto the radio-frequency carrier signal using amplitude modulation, the demodulator 322 demodulates the radio-frequency signal using envelope detection.

The clock phase-locked loop 323 is used to when an amplitude of the reference clock signal sent from the demodulator 322 meets an input power requirement of the clock phase-locked loop 323, by the clock phase-locked loop 323, synchronize a crystal oscillation signal generated by itself with the reference clock signal, and use the synchronized crystal oscillation signal as a reference clock signal at the MR wireless coil end 32.

Let the unlocking time margin of the clock phase-locked loop 323 be to. Then: when the amplitude of the reference clock signal sent from the demodulator 322 meets the input power requirement of the clock phase-locked loop 323, the clock phase-locked loop 323 locks in. That is, the clock phase-locked loop 323 synchronizes its own generated crystal oscillation signal with the received reference clock signal and uses the synchronized crystal oscillation signal as the reference clock signal of the MR wireless coil end 32. If the amplitude of the reference clock signal sent from the demodulator 322 does not meet the input power requirement of the clock phase-locked loop 323 within a duration t0, then when the timing duration reaches t0, the clock phase-locked loop 323 enters an unlocked state. At this time, the crystal oscillation signal of the clock phase-locked loop 323 is out of sync with a system clock signal of an MR system end 31. That is, the reference clock signal of the MR wireless coil end 32 is out of sync with the system clock signal of the MR system end 31.

When the clock phase-locked loop 323 enters the unlocked state, when it receives a reference clock signal sent from the demodulator 322 with an amplitude meeting the input power requirements of the clock phase-locked loop 323 again, the clock phase-locked loop 323 will enter a locked state from the unlocked state and restart synchronizing its own generated crystal oscillation signal with the reference clock signal.

In the embodiment of the present disclosure, the radio-frequency carrier frequency adjustment cycle is set to be less than the unlocking time margin of the clock phase-locked loop 323. Thus, when the first radio-frequency receiver 321 is in a blind spot position during a certain radio-frequency carrier frequency adjustment cycle, it can be ensured that the clock phase-locked loop 323 will not enter the unlocked state during that frequency adjustment cycle. Therefore, as long as the frequency in the next radio-frequency carrier frequency adjustment cycle is not the frequency corresponding to the blind spot position, it can be ensured that the reference clock signal of the next radio-frequency carrier frequency adjustment cycle can be received before the clock phase-locked loop 323 enters the unlocked state, thereby completely preventing the clock phase-locked loop 323 from entering the unlocked state.

Since the value of the radio-frequency carrier frequency adjustment step size is related to the width of the frequency range corresponding to the identical blind spot position, the width of the frequency range corresponding to the identical blind spot position must first be determined. In practical applications, the width of the frequency range corresponding to the identical blind spot position is measured using a blind spot measuring instrument. A specific implementation is as follows:

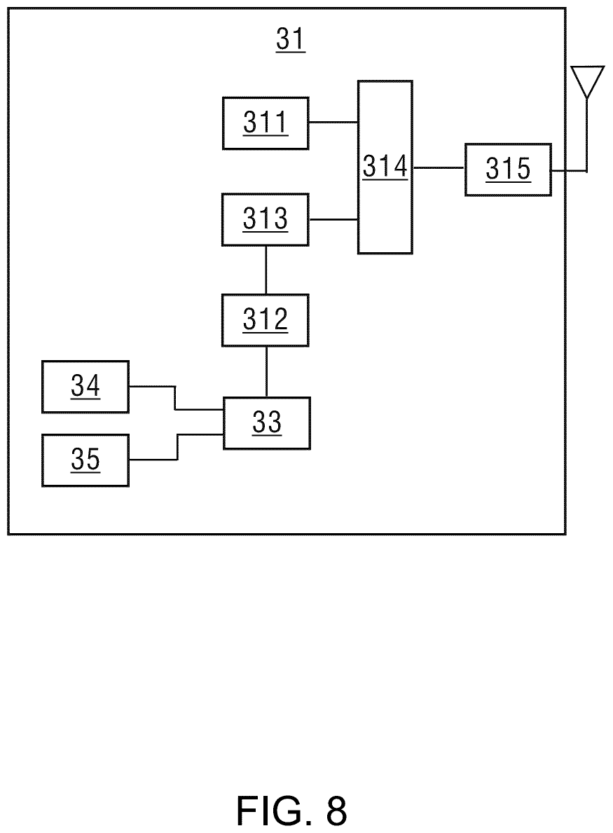

FIG. 8 is a schematic structural diagram of a wireless clock synchronization device for MR imaging provided in yet another embodiment of the present disclosure. As shown in FIG. 8, compared with the devices shown in FIGS. 3 and 7, the device shown in FIG. 8 has a blind spot measuring instrument 33, a test radio-frequency transmitter 34, and a test radio-frequency receiver 35 added. The blind spot measuring instrument 33 may have two ports which are exactly identical and assumed as a first port and a second port. The first port is connected to the test radio-frequency transmitter 34, and the second port is connected to the test radio-frequency receiver 35. The frequency bands of the test radio-frequency transmitter 34 and the test radio-frequency receiver 35 are the same as those of the first radio-frequency transmitter 315 and the first radio-frequency receiver 321. Both the test radio-frequency transmitter 34 and the test radio-frequency receiver 35 are located in an examination bore of MR examination equipment. The test radio-frequency transmitter 34 is fixed in position, and the test radio-frequency receiver 35 moves continuously during the measurement process. The wireless clock synchronization device may include processing circuitry configured to perform one or more functions and/or operations of the wireless clock synchronization device. Additionally, or alternatively, one or more components of wireless clock synchronization device may include processing circuitry that is configured to perform one or more respective functions of the component(s).

After the measurement begins, the blind spot measuring instrument 33 generates a frequency sweep signal at a certain rate within a supported frequency range and sends the frequency sweep signal to the test radio-frequency transmitter 34 through the first port. In addition, the test radio-frequency receiver 35 sends the received radio-frequency signal to the blind spot measuring instrument 33 through the second port. The blind spot measuring instrument 33 calculates the amplitude ratio between the signal received at the second port and the signal sent at the first port in real time and sends the amplitude ratio to the main controller 312.

The main controller 312 is further used to: when the amplitude ratio sent from the blind spot measuring instrument 33 is found to be less than a preset blind spot threshold, determine that the test radio-frequency receiver 35 is currently in a blind spot position of a signal emitted by the test radio-frequency transmitter 34, and record a correspondence between the frequency of the signal currently emitted by the test radio-frequency transmitter 34 and the blind spot position; when the measurement ends, determine a width of a frequency range corresponding to an identical blind spot position according to all recorded correspondences between frequencies and blind spot positions; and according to the width of the frequency range corresponding to the identical blind spot position, or according to the width of the frequency range corresponding to the identical blind spot position and a frequency range used by a radio-frequency antenna (including the first radio-frequency transmitter 315 and the first radio-frequency receiver 321), set the radio-frequency carrier frequency adjustment step size.

In practical applications, the widths of the frequency ranges corresponding to different blind spot positions are very close. At the end of the measurement, the main controller 312 may take the average of the widths of the frequency ranges corresponding to all blind spot positions as the width of the frequency range corresponding to the identical blind spot position for final use.

In practical applications, the blind spot measuring instrument 33 may also display a curve of the amplitude ratio between the signal received at the second port and the signal emitted at the first port as a function of the signal frequency in real time on a display screen. A user finds a blind spot and a corresponding frequency on the curve and record the correspondence between the frequency and the blind spot position. When the measurement ends, the user determines the width of the frequency range corresponding to the identical blind spot position according to all the recorded correspondences between frequencies and blind spot positions. According to the width of the frequency range corresponding to the identical blind spot position, or according to the width of the frequency range corresponding to the identical blind spot position and the frequency range used by the radio-frequency antenna (including the first radio-frequency transmitter 315 and the first radio-frequency receiver 321), the user sets a radio-frequency carrier frequency adjustment step size and then configures the radio-frequency carrier frequency adjustment step size to the main controller 312.

Throughout the measurement process, the blind spot measuring instrument 33 can perform multiple frequency sweeps across the frequency range used by the test radio-frequency transmitter 34 and the test radio-frequency receiver 35 to find blind spots at all frequencies as much as possible.

In practical applications, the blind spot measuring instrument 33 may be a vector network analyzer. A specific example of using the vector network analyzer for blind spot measurement will be provided below:

The vector network analyzer may have two radio-frequency ports, which are assumed as p1 and p2. It is assumed that p1 is connected to a radio-frequency antenna 1 within the 2.4 GHz band, and p2 is also connected to a radio-frequency antenna 2 within the 2.4 GHz band. The radio-frequency antenna 1 is fixed in the examination bore of the MR examination equipment, and the radio-frequency antenna 2 can move within the examination bore. The vector network analyzer continuously generates a sweep signal within the 2.4 GHz band. For example, if the supported frequency range of the 2.4 GHz band is 2.3 GHz-2.5 GHz, the vector network analyzer continuously generates radio-frequency signals within 2.3 GHz-2.5 GHz as sweep signals in accordance with a frequency gradient from low to high or high to low at a certain frequency step size. The vector network analyzer sends the sweep signal to the radio-frequency antenna 1 through p1. After receiving the signal, the radio-frequency antenna 2 transmits the signal to the vector network analyzer through p2. The vector network analyzer then calculates the amplitude ratio of the received signal to the emitted signal in real time. For ease of viewing, the amplitude ratio is further calculated using a logarithmic function, i.e.,

$$10 l g \frac{p 2}{p 1} .$$

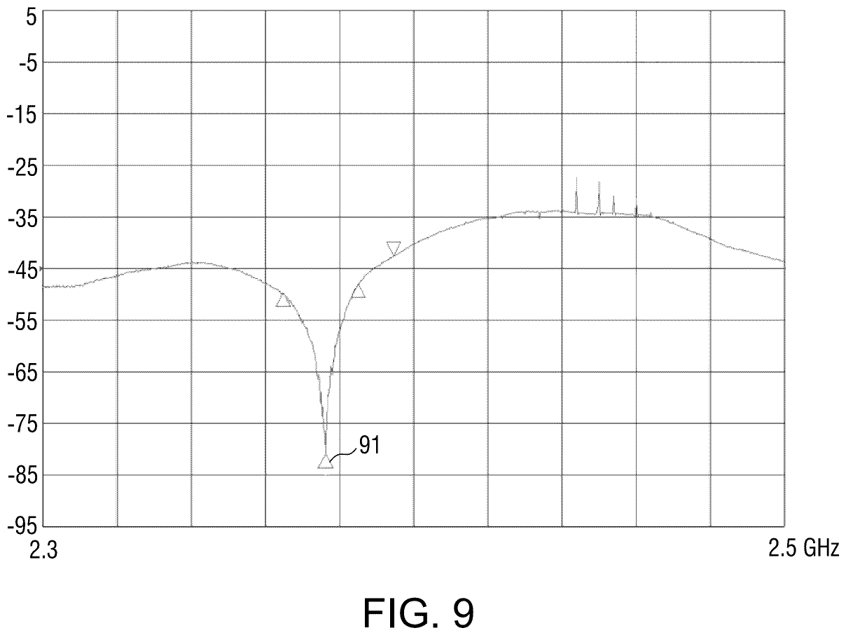

FIG. 9 shows a curve of

$$10 lg \frac{p 2}{p 1}$$

as a function of the frequency of a signal emitted by the radio-frequency antenna 1 when the radio-frequency antenna 2 moves to a certain position in the examination bore of the MR examination equipment, with both radio-frequency antennas 1 and 2 being in the 2.4 GHz band. The horizontal axis represents the frequency of the signal emitted by the radio-frequency antenna 1, with a frequency range of 2.3 GHz-2.5 GHz, and the vertical axis represents

$$10 l g \frac{p 2}{p 1} .$$

A blind spot threshold a is preset. If

$$10 l g \frac{p 2}{p 1}$$

of a certain point on the curve is less than the blind spot threshold a, the position corresponding to this point is determined as a blind spot at the frequency corresponding to this point. As shown in FIG. 9, point 91 corresponds to a frequency of 2.376 GHz. Since

$$10 lg \frac{p 2}{p 1}$$

corresponding to 2.376 GHz±10 MHz is less than the blind spot threshold a, the position of the radio-frequency antenna 2 at this time is a blind spot corresponding to 2.376 GHz±10 MHz.

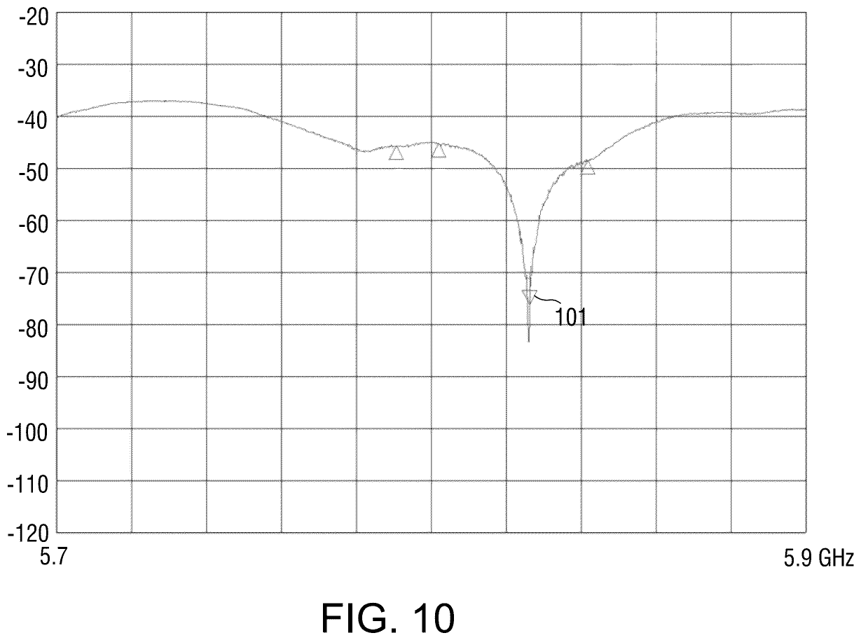

FIG. 10 shows a curve of

$$10 l g \frac{p 2}{p 1}$$

as a function of the frequency of a signal emitted by the radio-frequency antenna 1 when the radio-frequency antenna 2 moves to a certain position in the examination bore of the MR examination equipment, with both radio-frequency antennas 1 and 2 being in the 5.8 GHz band. The horizontal axis represents the frequency of the signal emitted by the radio-frequency antenna 1, with a frequency range of 5.7 GHz-5.9 GHz, and the vertical axis represents

$$10 l g \frac{p 2}{p 1} .$$

A blind spot threshold b is preset. If

$$10 lg \frac{p 2}{p 1}$$

of a certain point on the curve is less than the blind spot threshold b, the position corresponding to this point is determined as a blind spot at the frequency corresponding to this point. As shown in FIG. 10, point 101 corresponds to a frequency of 5.826 GHz. Since

$$10 lg \frac{p 2}{p 1}$$

corresponding to 5.826 GHz±10 MHz is less than the blind spot threshold b, the position of the radio-frequency antenna 2 at this time is a blind spot corresponding to 5.826 GHz±10 MHz.

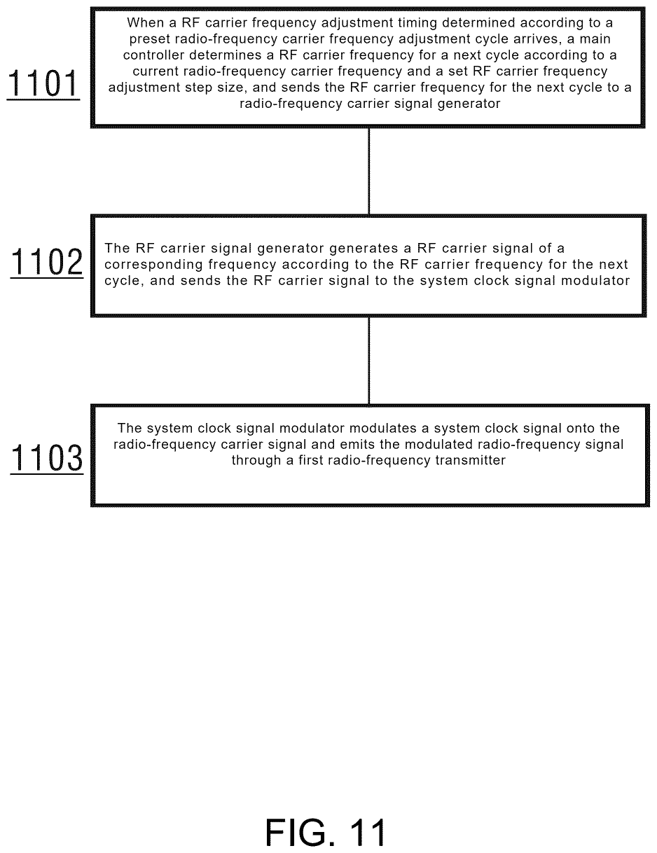

FIG. 11 is a flowchart of a wireless clock synchronization method for MR imaging provided in an embodiment of the present disclosure. As shown in FIG. 11, steps of the method are specifically as follows:

Step 1101: When a radio-frequency carrier frequency adjustment timing determined according to a preset radio-frequency carrier frequency adjustment cycle arrives, a main controller determines a radio-frequency carrier frequency for a next cycle according to a current radio-frequency carrier frequency and a set radio-frequency carrier frequency adjustment step size, and sends the radio-frequency carrier frequency for the next cycle to a radio-frequency carrier signal generator.

In an optional embodiment, a frequency adjustment cycle of the radio-frequency carrier signal is less than an unlocking time margin of a clock phase-locked loop at a magnetic resonance wireless coil end.

In an optional embodiment, the value of the radio-frequency carrier frequency adjustment step size is set according to a width of a frequency range corresponding to the identical blind spot position; or the value of the radio-frequency carrier frequency adjustment step size is set according to the width of the frequency range corresponding to the identical blind spot position and a frequency range actually used by the first radio-frequency transmitter; or the radio-frequency carrier frequency adjustment step size is greater than the width of the frequency range corresponding to the identical blind spot position; or the radio-frequency carrier frequency adjustment step size is not less than half the width of the frequency range corresponding to the identical blind spot position, and not greater than the width of the frequency range corresponding to the identical blind spot position.

Step 1102: The radio-frequency carrier signal generator generates a radio-frequency carrier signal of a corresponding frequency according to the radio-frequency carrier frequency for the next cycle, and sends the radio-frequency carrier signal to the system clock signal modulator.

Step 1103: The system clock signal modulator modulates a system clock signal onto the radio-frequency carrier signal and emits the modulated radio-frequency signal through a first radio-frequency transmitter.

In an optional embodiment, the radio-frequency carrier signal generator generating the radio-frequency carrier signal of the corresponding frequency according to the radio-frequency carrier frequency for the next cycle may include: by a frequency-to-voltage conversion module in the radio-frequency carrier signal generator, converting the radio-frequency carrier frequency for the next cycle into an input control voltage of a VCXO in the radio-frequency carrier signal generator according to the radio-frequency carrier frequency for the next cycle and a correspondence between output frequencies of the VCXO and input control voltages, and sending the input control voltage to the VCXO; and by the VCXO, receiving an input control voltage sent from a radio-frequency carrier frequency control module, generating a crystal oscillation signal with a frequency corresponding to the input control voltage, and using the crystal oscillation signal as a radio-frequency carrier signal.

In an optional embodiment, the radio-frequency carrier signal generator generating the radio-frequency carrier signal of the corresponding frequency according to the radio-frequency carrier frequency for the next cycle may include: by a digital signal generator in the radio-frequency carrier signal generator, determining a corresponding baseband frequency according to the radio-frequency carrier frequency for the next cycle sent from the main controller, generating a digital baseband signal according to the baseband frequency, and sending the digital baseband signal to a DAC in the radio-frequency carrier signal generator; by the DAC, converting the digital baseband signal into an analog baseband signal, and sending the analog baseband signal to a radio-frequency modulator in the radio-frequency carrier signal generator; and by the radio-frequency modulator, modulating the analog baseband signal onto a local oscillator signal to obtain a radio-frequency carrier signal with a frequency being the radio-frequency carrier frequency for the next cycle, and sending the radio-frequency carrier signal to the system clock signal modulator.

In an optional embodiment, the radio-frequency carrier signal generator generating the radio-frequency carrier signal of the corresponding frequency according to the radio-frequency carrier frequency for the next cycle may include: by a frequency controller in the radio-frequency carrier signal generator, determining a corresponding baseband frequency according to the radio-frequency carrier frequency for the next cycle sent from the main controller, and sending a frequency control command corresponding to the baseband frequency to a DDS in the radio-frequency carrier signal generator; by the DDS, parsing a baseband frequency from the frequency control command, generating an analog baseband signal according to the baseband frequency, and sending the analog baseband signal to a radio-frequency modulator in the radio-frequency carrier signal generator; and by the radio-frequency modulator, modulating the analog baseband signal onto a local oscillator signal to obtain a radio-frequency carrier signal with a frequency being the radio-frequency carrier frequency for the next cycle, and sending the radio-frequency carrier signal to the system clock signal modulator.

In an optional embodiment, before step 1101, the method further may include: by a blind spot measuring instrument, generating a frequency sweep signal at a certain rate within a supported frequency range and sending the frequency sweep signal to a test radio-frequency transmitter through a first port while a test radio-frequency receiver sends a received radio-frequency signal to the blind spot measuring instrument through a second port of the blind spot measuring instrument, and by the blind spot measuring instrument, calculating an amplitude ratio between a signal received at the second port and a signal sent from the first port in real time and sending the amplitude ratio to the main controller; and when the main controller finds that the amplitude ratio sent from the blind spot measuring instrument is less than a preset blind spot threshold, determining that the test radio-frequency receiver is currently in a blind spot of a signal emitted by the test radio-frequency transmitter, and recording a correspondence between the frequency of the signal currently emitted by the test radio-frequency transmitter and the blind spot position; when the measurement ends, determining a width of a frequency range corresponding to the identical blind spot position according to all recorded correspondences between frequencies and blind spot positions; and according to the width of the frequency range corresponding to the identical blind spot position, or according to the width of the frequency range corresponding to the identical blind spot position and a frequency range actually used by the first radio-frequency transmitter, setting the radio-frequency carrier frequency adjustment step size.

The embodiments of the present disclosure further provide an MR imaging system, the system including the wireless clock synchronization device for MR imaging as described above.

It should be noted that the wireless clock synchronization method and device for MR imaging, and the MR imaging system provided in the embodiments of the present disclosure may all be methods, device, and systems applied in medical imaging.

Those skilled in the art will understand that features stated in the various embodiments and/or claims disclosed in the present application can be combined and/or integrated in various ways, even if such combinations or integrations are not clearly stated in the present application. In particular, without departing from the spirit and teaching of the present application, features stated in the various embodiments and/or claims of the present application can be combined and/or integrated in various ways, and all such combinations and/or integrations fall within the scope of disclosure of the present application.

Specific embodiments have been used herein to expound the principles and implementations of the present application, but the description of the embodiments above is merely intended to help understand the method of the present application and the core idea thereof, not to restrict the present application. Those skilled in the art may change a specific implementation and application scope, based on the idea, spirit and principles of the present application, and any modifications, equivalent replacements, improvements, etc., which are made by those skilled in the art should be included within the scope of protection of the present application.

To enable those skilled in the art to better understand the solution of the present disclosure, the technical solution in the embodiments of the present disclosure is described clearly and completely below in conjunction with the drawings in the embodiments of the present disclosure. Obviously, the embodiments described are only some, not all, of the embodiments of the present disclosure. All other embodiments obtained by those skilled in the art on the basis of the embodiments in the present disclosure without any creative effort should fall within the scope of protection of the present disclosure.

It should be noted that the terms “first”, “second”, etc. in the description, claims and abovementioned drawings of the present disclosure are used to distinguish between similar objects, but not necessarily used to describe a specific order or sequence. It should be understood that data used in this way can be interchanged as appropriate so that the embodiments of the present disclosure described here can be implemented in an order other than those shown or described here. In addition, the terms “comprise” and “have” and any variants thereof are intended to cover non-exclusive inclusion. For example, a process, method, system, product or equipment comprising a series of steps or modules or units is not necessarily limited to those steps or modules or units which are clearly listed, but may comprise other steps or modules or units which are not clearly listed or are intrinsic to such processes, methods, products or equipment.

References in the specification to “one embodiment,” “an embodiment,” “an exemplary embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

The exemplary embodiments described herein are provided for illustrative purposes, and are not limiting. Other exemplary embodiments are possible, and modifications may be made to the exemplary embodiments. Therefore, the specification is not meant to limit the disclosure. Rather, the scope of the disclosure is defined only in accordance with the following claims and their equivalents.

Embodiments may be implemented in hardware (e.g., circuits), firmware, software, or any combination thereof. Embodiments may also be implemented as instructions stored on a machine-readable medium, which may be read and executed by one or more processors. A machine-readable medium may include any mechanism for storing or transmitting information in a form readable by a machine (e.g., a computer). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact results from computing devices, processors, controllers, or other devices executing the firmware, software, routines, instructions, etc. Further, any of the implementation variations may be carried out by a general-purpose computer.

The various components described herein may be referred to as “modules,” “units,” or “devices.” Such components may be implemented via any suitable combination of hardware and/or software components as applicable and/or known to achieve their intended respective functionality. This may include mechanical and/or electrical components, processors, processing circuitry, or other suitable hardware components, in addition to or instead of those discussed herein. Such components may be configured to operate independently, or configured to execute instructions or computer programs that are stored on a suitable computer-readable medium. Regardless of the particular implementation, such modules, units, or devices, as applicable and relevant, may alternatively be referred to herein as “circuitry,” “controllers,” “processors,” or “processing circuitry,” or alternatively as noted herein.

For the purposes of this discussion, the term “processing circuitry” shall be understood to be circuit(s) or processor(s), or a combination thereof. A circuit includes an analog circuit, a digital circuit, data processing circuit, other structural electronic hardware, or a combination thereof. A processor includes a microprocessor, a digital signal processor (DSP), central processor (CPU), application-specific instruction set processor (ASIP), graphics and/or image processor, multi-core processor, or other hardware processor. The processor may be “hard-coded” with instructions to perform corresponding function(s) according to aspects described herein. Alternatively, the processor may access an internal and/or external memory to retrieve instructions stored in the memory, which when executed by the processor, perform the corresponding function(s) associated with the processor, and/or one or more functions and/or operations related to the operation of a component having the processor included therein.

In one or more of the exemplary embodiments described herein, the memory is any well-known volatile and/or non-volatile memory, including, for example, read-only memory (ROM), random access memory (RAM), flash memory, a magnetic storage media, an optical disc, erasable programmable read only memory (EPROM), and programmable read only memory (PROM). The memory can be non-removable, removable, or a combination of both.

Reference List

| | |
|---|---|
| 11 | System end |
| 12 | Wireless coil end |
| 111 | System clock |
| 112 | Radio-frequency carrier signal generator |
| 113 | Amplitude modulator |
| 114 | Radio-frequency transmitter |
| 121 | Radio-frequency receiver |
| 122 | Envelope detection module |
| 123 | Clock phase-locked loop |
| 20 | Radio-frequency signal receiving area in |
| | examination bore of MR examination equipment |
| 21 | Wireless transmission blind spot area for |
| | signal with frequency f1 |
| 22 | Wireless transmission blind spot area for |
| | signal with frequency f2 |
| 23 | Wireless transmission blind spot area for |
| | signal with frequency f3 |
| 24 | Wireless transmission blind spot area for |
| | signal with frequency f4 |
| 31 | MR system end |
| 311 | System clock |
| 312 | Main controller |
| 313 | Radio-frequency carrier signal generator |
| 314 | System clock signal modulator |
| 315 | First radio-frequency transmitter |
| 3131 | Frequency-to-voltage conversion module |
| 3132 | VCXO |
| 3133 | Digital signal generator |
| 3134 | DAC |
| 3135 | Radio-frequency modulator |
| 3136 | Frequency controller |
| 3137 | DDS |
| 3138 | Radio-frequency modulator |
| 32 | MR wireless coil end |
| 321 | First radio-frequency receiver |
| 322 | Demodulator |
| 323 | Clock phase-locked loop |
| 33 | Blind spot measuring instrument |
| 34 | Test radio-frequency transmitter |
| 35 | Test radio-frequency receiver |
| 91 | Blind spot corresponding to 2.376 GHz |
| 101 | Blind spot corresponding to 5.826 GHz |
| 1101-1103 | Steps |

1. A wireless clock synchronization device for magnetic resonance imaging, comprising:
a system clock;
a main controller;
a radio-frequency carrier signal generator;
a system clock signal modulator; and
a first radio-frequency transmitter located at a magnetic resonance system end, wherein:
the system clock is configured to generate a system clock signal and output the system clock signal to the system clock signal modulator;
based on a radio-frequency carrier frequency adjustment timing determined according to a preset radio-frequency carrier frequency adjustment cycle arrives, the main controller is configured to determine a radio-frequency carrier frequency for a next cycle according to a current radio-frequency carrier frequency and a set radio-frequency carrier frequency adjustment step size, and send the radio-frequency carrier frequency for the next cycle to the radio-frequency carrier signal generator;
the radio-frequency carrier signal generator is configured to generate a radio-frequency carrier signal of a corresponding frequency according to the radio-frequency carrier frequency for the next cycle, and sends the radio-frequency carrier signal to the system clock signal modulator;
the system clock signal modulator is configured to modulate a system clock signal onto the radio-frequency carrier signal and emits the modulated radio-frequency signal; and
the first radio-frequency transmitter is configured to emit the radio-frequency signal emitted from the system clock signal modulator.

2. The device as claimed in claim 1, wherein a frequency adjustment cycle of the radio-frequency carrier signal in the main controller is less than an unlocking time margin of a clock phase-locked loop at a magnetic resonance wireless coil end.

3. The device as claimed in claim 1, wherein:
a value of the radio-frequency carrier frequency adjustment step size in the main controller is set according to: (a) a width of a frequency range corresponding to an identical blind spot position, or (b) the width of the frequency range corresponding to the identical blind spot position and a frequency range actually used by the first radio-frequency transmitter; and/or
the radio-frequency carrier frequency adjustment step size in the main controller is: (a) greater than the width of the frequency range corresponding to the identical blind spot position, or (b) not less than half the width of the frequency range corresponding to the identical blind spot position, and not greater than the width of the frequency range corresponding to the identical blind spot position.

4. The device as claimed in claim 1, wherein the radio-frequency carrier signal generator comprises: a frequency-to-voltage converter and a voltage controlled crystal oscillator, wherein:
the frequency-to-voltage converter is configured to: convert the radio-frequency carrier frequency for the next cycle sent from the main controller into an input control voltage of the voltage controlled crystal oscillator according to the radio-frequency carrier frequency for the next cycle and a correspondence between output frequencies of the voltage controlled crystal oscillator and input control voltages, and send the input control voltage to the voltage controlled crystal oscillator; and
the voltage controlled crystal oscillator is configured to: receive the input control voltage sent from the frequency-to-voltage converter, generate a crystal oscillation signal with a frequency corresponding to the input control voltage, use the crystal oscillation signal as a radio-frequency carrier signal, and send the radio-frequency carrier signal to the system clock signal modulator.

5. The device as claimed in claim 1, wherein the radio-frequency carrier signal generator comprises: a digital signal generator, a digital-to-analog converter, and a radio-frequency modulator, wherein:
the digital signal generator is configured to: determine a corresponding baseband frequency according to the radio-frequency carrier frequency for the next cycle sent from the main controller, generate a digital baseband signal according to the baseband frequency, and send the digital baseband signal to the digital-to-analog converter;
the digital-to-analog converter is configured to: receive the digital baseband signal sent from the digital signal generator, convert the digital baseband signal into an analog baseband signal, and send the analog baseband signal to the radio-frequency modulator;
the radio-frequency modulator is configured to: modulate the analog baseband signal onto a local oscillator signal to obtain a radio-frequency carrier signal with a frequency being the radio-frequency carrier frequency for the next cycle, and send the radio-frequency carrier signal to the system clock signal modulator.

6. The device as claimed in claim 1, wherein the radio-frequency carrier signal generator comprises: a frequency controller, a direct digital synthesizer, and a radio-frequency modulator, wherein:
the frequency controller is configured to: determine a corresponding baseband frequency according to the radio-frequency carrier frequency for the next cycle sent from the main controller, and send a frequency control command corresponding to the baseband frequency to the direct digital synthesizer;
the direct digital synthesizer is configured to: parse a baseband frequency from the frequency control command, generate an analog baseband signal according to the baseband frequency, and send the analog baseband signal to the radio-frequency modulator;
the radio-frequency modulator is configured to: modulate the analog baseband signal onto a local oscillator signal to obtain a radio-frequency carrier signal with a frequency being the radio-frequency carrier frequency for the next cycle, and send the radio-frequency carrier signal to the system clock signal modulator.

7. The device as claimed in claim 1, wherein the device further comprises: a first radio-frequency receiver, a demodulator, and a clock phase-locked loop located at a magnetic resonance wireless coil end, wherein:
the first radio-frequency receiver is configured to receive a radio-frequency signal from the first radio-frequency transmitter and send the radio-frequency signal to the demodulator;
the demodulator is configured to demodulate the radio-frequency signal to obtain a signal with a frequency equal to the system clock frequency, and send the signal as a reference clock signal to the clock phase-locked loop; and
based on an amplitude of the reference clock signal sent from the demodulator meeting an input power requirement of the clock phase-locked loop, the clock phase-locked loop is configured to synchronize a crystal oscillation signal generated by itself with the reference clock signal, and use the synchronized crystal oscillation signal as a reference clock signal at the magnetic resonance wireless coil end.

8. The device as claimed in claim 1, further comprising: a blind spot measuring instrument, a test radio-frequency transmitter, and a test radio-frequency receiver, wherein:
the blind spot measuring instrument includes two ports, a first port connected to the test radio-frequency transmitter and a second port connected to the test radio-frequency receiver, frequency bands of the test radio-frequency transmitter and the test radio-frequency receiver being the same as a frequency band of the first radio-frequency transmitter, both the test radio-frequency transmitter and the test radio-frequency receiver being located inside an examination bore of magnetic resonance examination equipment, the test radio-frequency transmitter being fixed in position, and the test radio-frequency receiver moving continuously in a measurement process;
the blind spot measuring instrument is configured to: generate a frequency sweep signal at a certain rate within a supported frequency range and sends the frequency sweep signal to the test radio-frequency transmitter through the first port while the test radio-frequency receiver sends a received radio-frequency signal to the blind spot measuring instrument through the second port, calculate an amplitude ratio between a signal received at the second port and a signal sent from the first port in real time, and send the amplitude ratio to the main controller; and
the main controller is further configured to:
based on the amplitude ratio sent from the blind spot measuring instrument being less than a preset blind spot threshold, determine that the test radio-frequency receiver is currently in a blind spot of a signal emitted by the test radio-frequency transmitter, and record a correspondence between the frequency of the signal currently emitted by the test radio-frequency transmitter and the blind spot position, and
based on the measurement ending, determine a width of a frequency range corresponding to an identical blind spot position according to all recorded correspondences between frequencies and blind spot positions, and according to the width of the frequency range corresponding to the identical blind spot position or according to the width of the frequency range corresponding to the identical blind spot position and a frequency range actually used by the first radio-frequency transmitter, set the radio-frequency carrier frequency adjustment step size.

9. A wireless clock synchronization method in magnetic resonance imaging, the method comprising:
based on an arrival of a radio-frequency carrier frequency adjustment timing determined according to a preset radio-frequency carrier frequency adjustment cycle, determining, by a main controller, a radio-frequency carrier frequency for a next cycle according to a current radio-frequency carrier frequency and a set radio-frequency carrier frequency adjustment step size, and sending, by the main controller, the radio-frequency carrier frequency for the next cycle to a radio-frequency carrier signal generator;
generating, by the radio-frequency carrier signal generator, a radio-frequency carrier signal of a corresponding frequency according to the radio-frequency carrier frequency for the next cycle, and sending, by the radio-frequency carrier signal generator, the radio-frequency carrier signal to a system clock signal modulator; and
modulating, by the system clock signal modulator, a system clock signal onto the radio-frequency carrier signal and transmitting the modulated radio-frequency signal through a first radio-frequency transmitter.

10. The method as claimed in claim 9, wherein a frequency adjustment cycle of the radio-frequency carrier signal is less than an unlocking time margin of a clock phase-locked loop at a magnetic resonance wireless coil end.

11. The method as claimed in claim 9, wherein:
a value of the radio-frequency carrier frequency adjustment step size is set: (a) according to a width of a frequency range corresponding to an identical blind spot position, or (b) according to the width of the frequency range corresponding to the identical blind spot position and a frequency range actually used by the first radio-frequency transmitter; and/or
the radio-frequency carrier frequency adjustment step size is: (a) greater than the width of the frequency range corresponding to the identical blind spot position, or (b) not less than half the width of the frequency range corresponding to the identical blind spot position, and not greater than the width of the frequency range corresponding to the identical blind spot position.

12. The method as claimed in claim 9, wherein the generating the radio-frequency carrier signal of the corresponding frequency, by the radio-frequency carrier signal generator and according to the radio-frequency carrier frequency for the next cycle, comprises:
converting, by a frequency-to-voltage converter in the radio-frequency carrier signal generator, the radio-frequency carrier frequency for the next cycle into an input control voltage of a voltage controlled crystal oscillator in the radio-frequency carrier signal generator according to the radio-frequency carrier frequency for the next cycle and a correspondence between output frequencies of the voltage controlled crystal oscillator and input control voltages, and sending the input control voltage to the voltage controlled crystal oscillator; and
generating, by the voltage controlled crystal oscillator, a crystal oscillation signal with a frequency corresponding to the received input control voltage according to the input control voltage, and using the crystal oscillation signal as a radio-frequency carrier signal.

13. The method as claimed in claim 9, wherein the generating the radio-frequency carrier signal of the corresponding frequency, by the radio-frequency carrier signal generator and according to the radio-frequency carrier frequency for the next cycle, comprises:
determining, by a digital signal generator in the radio-frequency carrier signal generator, a corresponding baseband frequency according to the radio-frequency carrier frequency for the next cycle sent from the main controller, generating, by the digital signal generator, a digital baseband signal according to the baseband frequency, and sending, by the digital signal generator, the digital baseband signal to a digital-to-analog converter in the radio-frequency carrier signal generator;
converting, by the digital-to-analog converter, the digital baseband signal into an analog baseband signal, and sending the analog baseband signal to a radio-frequency modulator in the radio-frequency carrier signal generator; and
modulating, by the radio-frequency modulator, the analog baseband signal onto a local oscillator signal to obtain a radio-frequency carrier signal with a frequency being the radio-frequency carrier frequency for the next cycle.

14. The method as claimed in claim 9, wherein the generating the radio-frequency carrier signal of the corresponding frequency, by the radio-frequency carrier signal generator and according to the radio-frequency carrier frequency for the next cycle, comprises:
determining, by a frequency controller in the radio-frequency carrier signal generator, a corresponding baseband frequency according to the radio-frequency carrier frequency for the next cycle sent from the main controller, and sending a frequency control command corresponding to the baseband frequency to a direct digital synthesizer in the radio-frequency carrier signal generator;
parsing, by the direct digital synthesizer, a baseband frequency from the frequency control command, generating an analog baseband signal according to the baseband frequency, and sending the analog baseband signal to a radio-frequency modulator in the radio-frequency carrier signal generator; and
modulating, by the radio-frequency modulator, the analog baseband signal onto a local oscillator signal to obtain a radio-frequency carrier signal with a frequency being the radio-frequency carrier frequency for the next cycle.

15. The method as claimed in claim 9, wherein before the main controller determines the arrival of the radio-frequency carrier frequency adjustment timing according to the preset radio-frequency carrier frequency adjustment cycle, the method further comprises:
generating, by a blind spot measuring instrument, a frequency sweep signal at a certain rate within a supported frequency range and sending the frequency sweep signal to a test radio-frequency transmitter through a first port while a test radio-frequency receiver sends a received radio-frequency signal to the blind spot measuring instrument through a second port of the blind spot measuring instrument;
calculating, by the blind spot measuring instrument, an amplitude ratio between a signal received at the second port and a signal sent from the first port in real time and sending the amplitude ratio to the main controller;
based on the main controller determining that the amplitude ratio sent from the blind spot measuring instrument is less than a preset blind spot threshold, determining that the test radio-frequency receiver is currently in a blind spot of a signal emitted by the test radio-frequency transmitter, and recording a correspondence between the frequency of the signal currently emitted by the test radio-frequency transmitter and the blind spot position;
based on the measurement ending, determining, main controller, a width of a frequency range corresponding to an identical blind spot position according to all recorded correspondences between frequencies and blind spot positions; and
according to the width of the frequency range corresponding to the identical blind spot position, or according to the width of the frequency range corresponding to the identical blind spot position and a frequency range actually used by the first radio-frequency transmitter, setting, by the main controller, the radio-frequency carrier frequency adjustment step size.

16. A magnetic resonance imaging system comprising the wireless clock synchronization device according to claim 1.

17. One or more non-transitory media storing instructions that, when executed by one or more processors, cause the one or more processors to perform the method of claim 9.
